(19) United States
(12) Patent Application Publication
(10) Pub. No.: US 2004/0212962 A1
(43) Pub. Date: Oct. 28, 2004

(54) Lateral airflow fan-sink for electronic devices

(75) Inventor: Shih-Chang Ku, Taipei (TW)

Correspondence Address: BRUCE H. TROXELL, SUITE 1404, 5205 LEESBURG PIKE, FALLS CHURCH, VA, 22041, US

(73) Assignee: Via Technologies, Inc.

(21) Appl. No.: 10/609,594

(22) Filed: Jul. 1, 2003

(30) Foreign Application Priority Data
Apr. 11, 2003 (TW) 92205721

(51) Int. Cl. H05K 7/20

(52) U.S. Cl. 361/697

(57) ABSTRACT

A lateral airflow fan-sink for electronic devices is introduced to comprise a heat-fin with inter-fin slots and a plurality of axial fans surrounding the heat-fin. The axial fans are mounted individually at ventilating sides of the heat-fin for generating respective forced flow wiping through the inter-fin slots. Thereby, overall heat-dissipation efficiency of the fan-sink can be improved and operational jeopardy from breakdown of all axial fans can be totally removed.

### BACKGROUND OF THE INVENTION

(1) Field of the Invention

The invention relates to a lateral airflow fan-sink for electronic devices, and more particularly to a reliable and efficient combination which includes a heat-sink and several axial fans surrounding the heat-sink for generating forced wiping airflow over the heat-sink.

(2) Description of the Prior Art

In design of hi-speed chips such as the central processing unit, the south/north bridge chipset, graphics processor and so on, the heat-dissipation problem is always one of major concerns. Especially upon the demand of enhancing the operational power and speed of electronic devices, the recipe to resolve the heat-dissipation problem is usually treated as a bottleneck technique.

In the art, a hi-power electronic device is usually equipped with a heat-fin, or so-called heat sink, for forming a heat-dissipating mechanism upon the device. Generally, the connection between the heat-fin and the electronic device is a solid contact. In case that upgrading the heat-dissipation capability of the electronic device with a heat-fin is demanding, a single axial fan is usually introduced to top the heat-fin for forming the so-called fan heat-sink or fan-sink.

Referring to FIG. 1A and FIG. 1B, a perspective view and its schematic view of a conventional impinging fan-sink in application are respectively shown. As illustrated, the axial fan 16 is mounted in an impinging pattern for introducing an external flow 20 onto the heat-fin 14. upon such an arrangement, the heat generated by the electronic device 12 (on the printed circuit board 10) is dissipated through the heat-fin 14 and is further wiped away by the forced flow 21 passing by the inter-fin slots 141 of the heat-fin 14. Definitely, the forced flow 21 is formed by the sucking of the impinging axial fan 16. In this description, a side of the heat-fin 14 that allows the inter-fin slot 141 to form an opening end is defined as a ventilating side, and a side of the heat-fin 14 that does not connect with the inter-fin slot 141 is defined as a non-flow side. Obviously, the ventilating side 140 has the forced flow 21 to pass by.

Referring now to FIG. 2A and FIG. 2B, a perspective view and its schematic view of another conventional impinging fan-sink in application are respectively shown. Though the axial fan 16 as shown is also an impinging type, yet the air flow is totally different to the previous one shown in FIG. 1A. In the application, the axial fan 16 is used to generate an outward forced flow 21′ which induces the external flow 20′ to be sucked into the heat-fin 14′ through the ventilating side 140, then driven through the inter-fin slots 141, and finally sent through the axial fan 16. As shown, in this fan-sink of FIG. 2A or FIG. 2B, the square heat-fin 14′ is structured to have crossed inter-fin slots 141 so that all four sides of the heat-fin 14′ are the ventilating sides 140 and no non-flow side 142 exists in the this heat-fin 14′.

In two foregoing applications, the axial fan 16 of FIG. 1A can be called as a sucking-type fan for introducing the external flow 20 into the heat-fin 16. On the other hand, the axial fan 16′ of FIG. 2A can be named as an exhausting-type fan which discharges the air in the heat-fin 14′ to the surroundings.

In case that the conventional heat-dissipating impinging fan-sink needs to be upgraded in heat dissipation, various improvements such as increasing the height of fins, increasing the number of fins, or broadening the surface of the fin can be considered. Nevertheless, accompanying with the improvement of the heat-fin, the capacity of the axial fan also needs to be increased as well so that additional flow resistance resulted from improving the heat-fin can be compensated. It is obvious that, in a limited installation space, the capacity of the axial fan can only be upgraded by increasing the operational speed or power of the axial fan. As a result of such improvement, the noise level of the axial fan will be elevated and the lifetime, on the other hand, will be shortened. In addition, when the volume of the impinging heat fan is increased, the total height and weight loaded on the electronic device will be increased as well, and thereby the merits derived from using a slim electronic device will be definitely erased.

Moreover, the usage of a single axial fan will also lead to a reliability concern upon the system having the heat fan. Provided that the axial fan is out of order by anyhow, then no forced flow can be contributed to the inter-fin slots for carrying the heat away. Further, because the axial fan is located on top of the heat-fin, the flow field above the heat-fin is actually occupied by the wrecked axial fan and thus a stall area is formed which is surely negative to the heat dissipation of the electronic devices. Therefore, the application of a single impinging axial fan in a conventional fan-sink does need to be improved in consideration of heat dissipation of the whole electronic system.

### SUMMARY OF THE INVENTION

Accordingly, it is a primary object of the present invention to provide a lateral airflow fan-sink for electronic devices which mounts several axial fans at the ventilating sides of a heat-fin so as to have the axial fans produce straight forced flows to flow or wipe along inter-fin slots and to free the ventilation space right above the heat-fin, and thereby overall heat-dissipation efficiency of the fan-sink can thus be improved over the conventional top-mounted impinging fan-sink. Further, the usage of multiple axial fans in the fan-sink of the present invention can prevent the electronic device applying the fan-sink from breakdown while one of the axial fan damages.

The lateral airflow fan-sink for electronic devices in accordance with the present invention comprises a heat-fin and a plurality of axial fans mounted at the ventilating sides of the heat-fin.

The heat-fin of the present invention further includes a plurality of inter-fin slots. The arrangement of the inter-fin slots can be a parallel type, a crossed type, or any proper type. At the heat-fin, opposing sides connected longitudinally by any inter-fin slot are defined as opposing ventilating sides. In practice, the ventilating side allow the air to pass through, both in and out of the inter-fin slot.

The axial fans of the present invention are mounted at the ventilating sides of the heat-fin to generate forced flows flowing along the respective inter-fin slots. By the axial fans providing the forced flows wiping through the inter-fin slots, the heat generated by the electronic device bottoming the heat-fin and transmitted upward to the fins can then be quickly carried away.

In one embodiment of the present invention, the lateral airflow fan-sink for electronic devices can include at least a sucking-type fan among the axial fans, by which surrounding air can be sucked into the space over the heat-fin so as to perform heat exchange with the fins.

In one embodiment of the present invention, the lateral airflow fan-sink for electronic devices can include at least an exhausting-type fan among the axial fans, by which the air in the space over the heat-fin can be drawn out of the fan-sink to the surroundings.

In one embodiment of the present invention, the lateral airflow fan-sink for electronic devices can further include an air shield mounted over the axial fans and extended to cover the inter-fin slots so that the induced forced flow over the heat-fin can only flow under the air shield and above the heat-fin.

Preferably, the opposing ventilating sides of the lateral airflow fan-sink for electronic devices in accordance with the present invention can have respective axial fans. In another embodiment of the present invention, the opposing ventilating sides can be also arranged to have only one axial fan.

In the present invention, the forced flow introduced by the axial fan can be a flow parallel to or at a predetermined angle with the inter-fin slots.

All these objects are achieved by the lateral airflow fan-sink for electronic devices described below.

### BRIEF DESCRIPTION OF THE DRAWINGS

The present invention will now be specified with reference to its preferred embodiment illustrated in the drawings, in which

FIG. 1A is a perspective view of a conventional impinging fan-sink in application;

FIG. 1B is a schematic perspective view of FIG. 1A;

FIG. 2A is a perspective view of another conventional impinging fan-sink in application;

FIG. 2B is a schematic perspective view of FIG. 2A;

FIG. 3A is a perspective view of a first embodiment of the lateral airflow fan-sink for electronic devices in accordance with the present invention in application;

FIG. 3B is a schematic perspective view of FIG. 3A;

FIG. 3C is a symbolic top view of FIG. 3A;

FIG. 4A is a schematic perspective view of a second embodiment of the lateral airflow fan-sink for electronic devices in accordance with the present invention in application;

FIG. 4B is a symbolic top view of FIG. 4A;

FIG. 5 is a symbolic top view of a third embodiment of the lateral airflow fan-sink for electronic devices in accordance with the present invention;

FIG. 6 is a symbolic top view of a fourth embodiment of the lateral airflow fan-sink for electronic devices in accordance with the present invention,

FIG. 7 is a symbolic top view of a fifth embodiment of the lateral airflow fan-sink for electronic devices in accordance with the present invention;

FIG. 8 is a symbolic top view of a sixth embodiment of the lateral airflow fan-sink for electronic devices in accordance with the present invention;

FIG. 9 is a symbolic top view of a seventh embodiment of the lateral airflow fan-sink for electronic devices in accordance with the present invention;

FIG. 10 is a symbolic top view of an eighth embodiment of the lateral airflow fan-sink for electronic devices in accordance with the present invention;

FIG. 11 is a symbolic top view of a ninth embodiment of the lateral airflow fan-sink for electronic devices in accordance with the present invention;

FIG. 12 is a symbolic top view of a tenth embodiment of the lateral airflow fan-sink for electronic devices in accordance with the present invention;

FIG. 13 is a symbolic top view of an eleventh embodiment of the lateral airflow fan-sink for electronic devices in accordance with the present invention;

FIG. 14 is a symbolic top view of a twelfth embodiment of the lateral airflow fan-sink for electronic devices in accordance with the present invention;

FIG. 15 is a symbolic top view of a thirteenth embodiment of the lateral airflow fan-sink for electronic devices in accordance with the present invention;

FIG. 16 is a symbolic top view of a fourteenth embodiment of the lateral airflow fan-sink for electronic devices in accordance with the present invention;

FIG. 17 is a symbolic top view of a fifteenth embodiment of the lateral airflow fan-sink for electronic devices in accordance with the present invention;

FIG. 18 is a symbolic top view of a sixteenth embodiment of the lateral airflow fan-sink for electronic devices in accordance with the present invention;

FIG. 19 is a schematic perspective view of a seventeenth embodiment of the lateral airflow fan-sink for electronic devices in accordance with the present invention in application;

FIG. 20 is a schematic perspective view of an eighteenth embodiment of the lateral airflow fan-sink for electronic devices in accordance with the present invention in application; and

FIG. 21 is a cross-sectional view showing the relationship between the axial fan and the heat-fin of the lateral airflow fan-sink for electronic devices in accordance with the present invention.

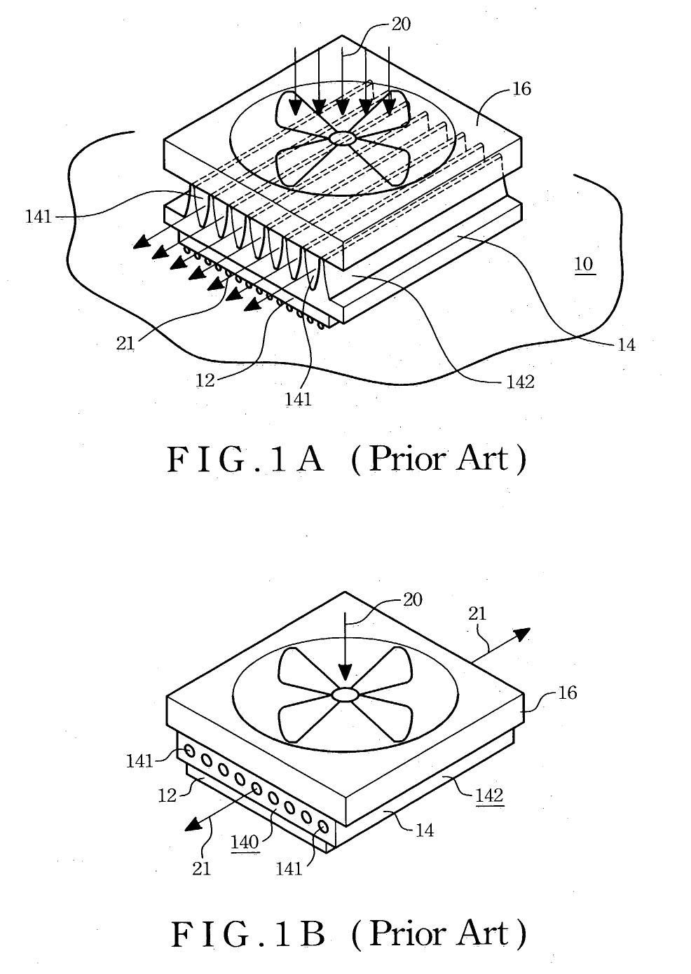

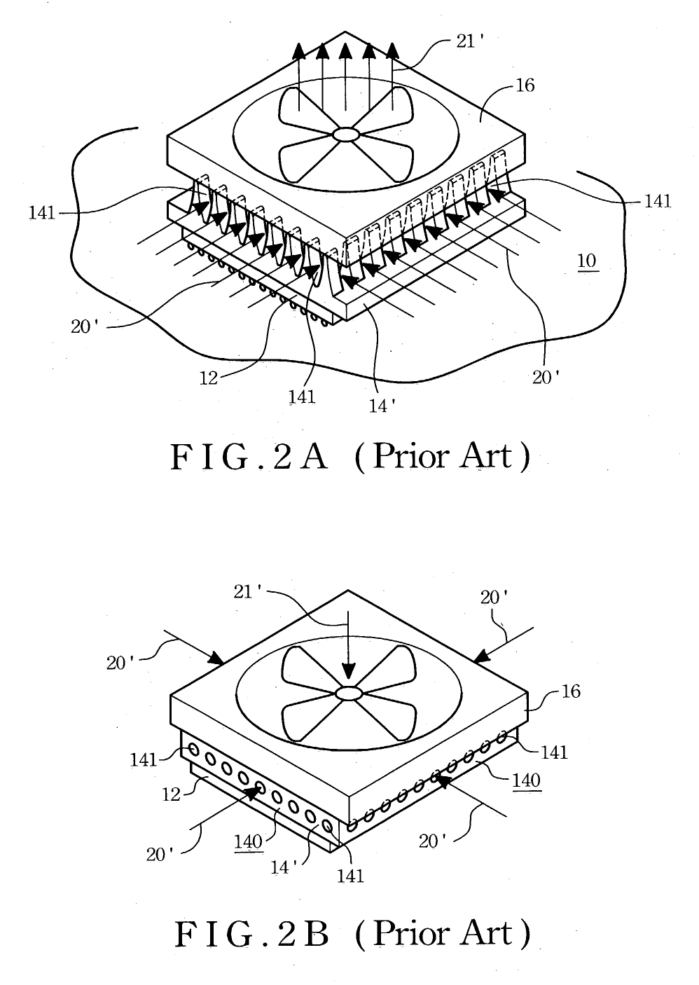

### DESCRIPTION OF THE PREFERRED EMBODIMENT

The invention disclosed herein is directed to a lateral airflow fan-sink for electronic devices. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

The design concept of the present invention is to move the axial fan to a lateral side of the heat-fin, from a conventional top-mounting position described in the background section. Also in the present invention, at least one axial fan is introduced to the proper lateral side of the heat-fin. Advantages from those improvements are various. One is that the space over the heat-fin can be free for heat dissipation by removing the top-mounted fan, so that the ventilation over the heat-fin can be improved to a substantial extend in case that the fan is damaged. Another is that the controllability of the forced flow can be enhanced by the lateral-mounted fans. One more obvious advantage is that the reliability of the whole system, including at least the fan-sink and the electronic device, can be increased by providing a plurality of axial fans to the heat-fin.

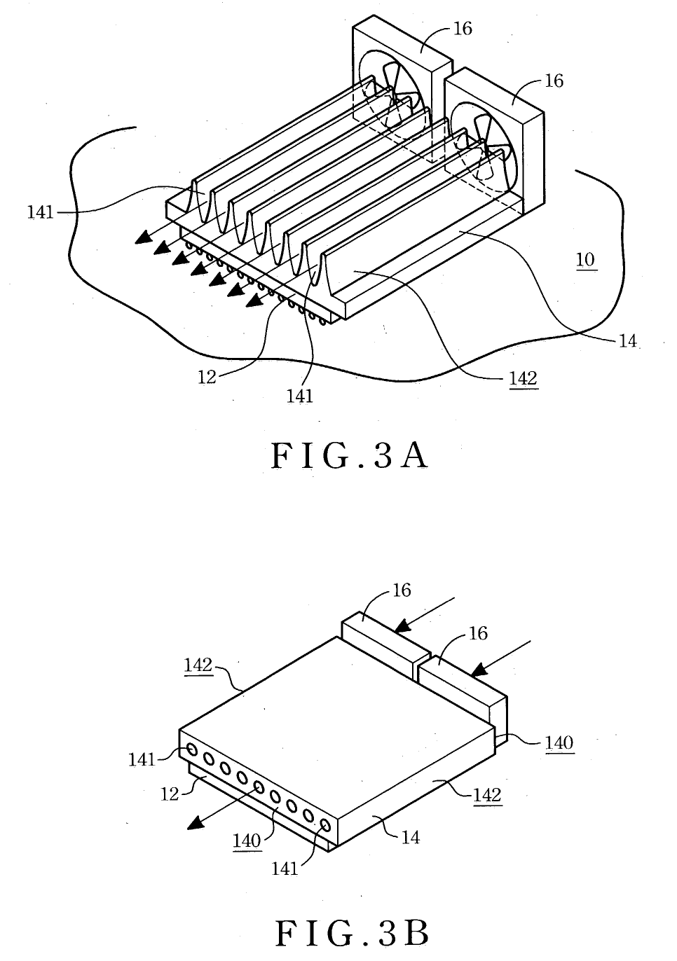

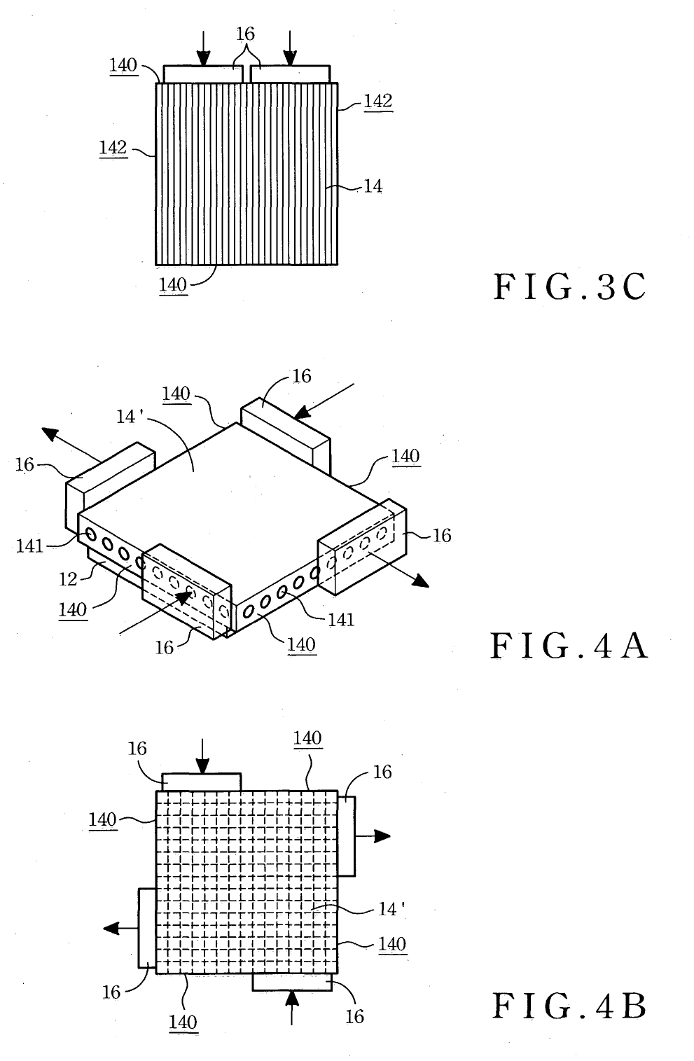

Referring now to FIG. 3A, FIG. 3B and FIG. 3C, a perspective view, a schematic perspective view and a symbolic top view of a first embodiment of the lateral airflow fan-sink for electronic devices in accordance with the present invention in application are shown, respectively. In this embodiment, the lateral airflow fan-sink, mounted on an electronic device 12 which is planted on a printed circuit board 10, includes a heat-fin 14 and a plurality of axial fans 16 mounting at lateral sides of the heat-fin 14 (two axial fans 16 mounted at the same side the figures).

In the first embodiment of the present invention, the heat-fin 14 has a plurality of parallel inter-fin slots 141. In this specification, the opposing sides of the heat-fin 14 which connect longitudinally by any inter-fin slot 141 are defined as the opposing ventilating sides 140. Obviously, the ventilating side 140 is a side that allows air to pass through, both in and out of the corresponding inter-fin slots 141.

Each of the axial fans 16 of the present invention is individually mounted at the ventilating side 140 of the heat-fin 14 form generating a forced flow to wipe through the respective inter fin slots 141. The induced forced flow is provided to help the heat-fin to dissipate the heat generated by the electronic device 12. As shown, the two axial fans 16 of the first embodiment which are mounted at the same ventilating side 140 can provide the user a better control upon the direction of the forced flow.

As shown, FIG. 3B and FIG. 3C are simplified figures to illustrate those shown in FIG. 3A. From FIG. 3A through FIG. 3C, the arrows are used to represent the direction of air flow. Parallel lines on the heat-fin 14 of FIG. 3C are used to simplify the arrangement of the inter-fin slots 141 of the first embodiment. By viewing and then understanding the relationships among these three figures, following detail explanations upon the present invention will be easier.

Referring now to FIG. 4A and FIG. 4B, a schematic perspective view and a symbolic top view of a second embodiment of the lateral airflow fan-sink for electronic devices in accordance with the present invention in application are shown, respectively. In the embodiment, the lateral airflow fan-sink includes a heat-fin 14 with crossed inter-fin slots 141 (typically, perpendicularly crossed) and four axial fans 16 mounted at the four ventilating sides 140 of the heat-fin 14 with each 16 at one ventilating side 140.

In foregoing two embodiments, the two axial fans 16 of the first embodiment are both sucking-type fans which suck external air into the fan-sink for heat-exchange, while the second embodiment includes two sucking-type fans and two exhausting-type fans which force the air in the fan-sink out of the heat-fin 14 through this type of axial fans 14.

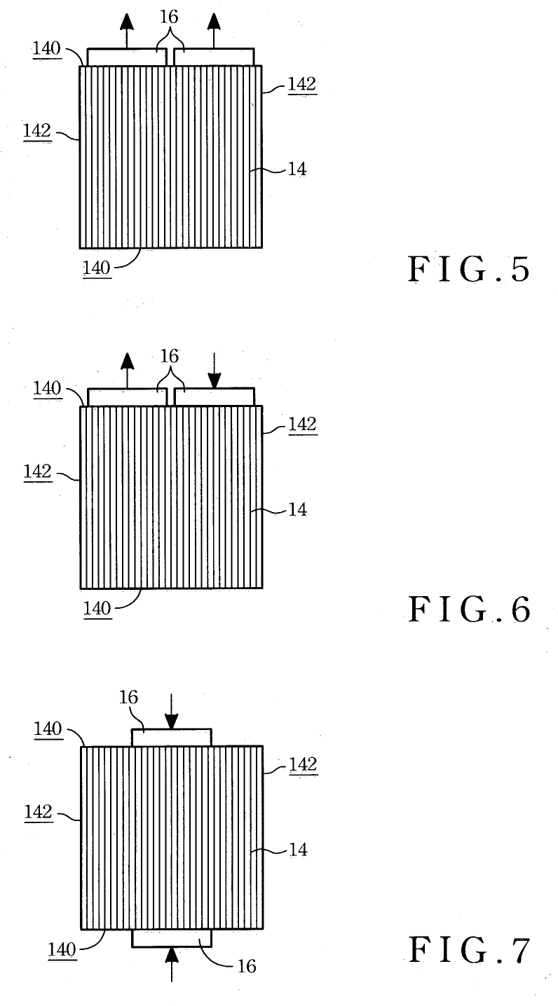

Following, FIG. 5 to FIG. 12 are symbolic top views of a third to a tenth embodiments of the lateral airflow fan-sink for electronic devices in accordance with the present invention, respectively. In each of these embodiments, two axial fans 16 are included and the inter-fin slots 141 of the heat-fin 14 are parallel arranged.

As shown in FIG. 5, the axial fans 16 of this embodiment are arranged at the same ventilating side 140 and both of them are exhausting-type fans.

As shown in FIG. 6, the axial fans 16 of this embodiment are still arranged at the same ventilating side 140, but one of the axial fans 16 is an exhausting-type fan while the other is a sucking-type fan.

As shown in FIG. 7, the axial fans 16 of this embodiment are arranged at the opposing ventilating sides 140 and both of them are sucking-type fans.

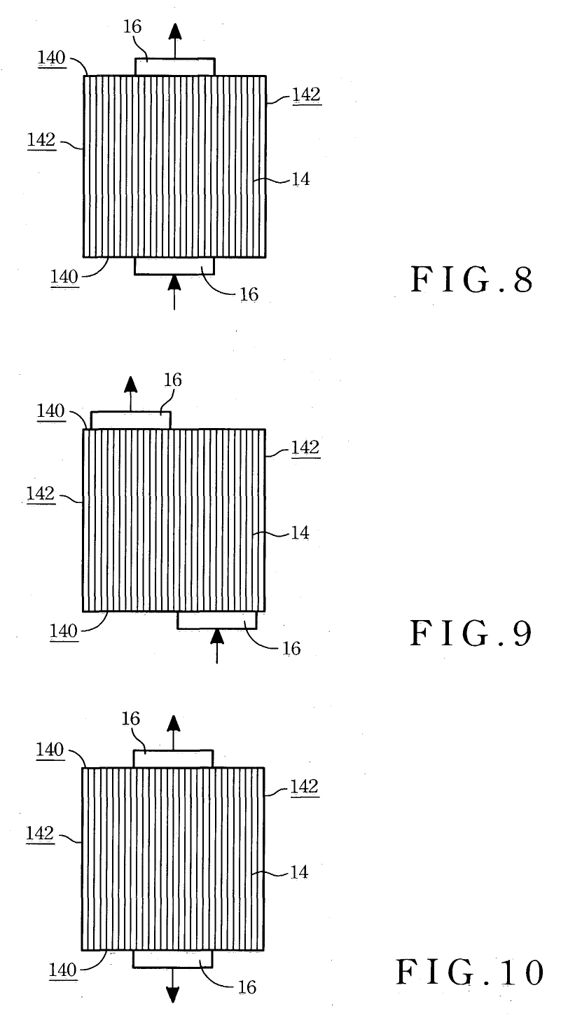

As shown in FIG. 8, the axial fans 16 of this embodiment are also arranged at the opposing ventilating sides 140, with one exhausting-type fan and one sucking-type fan.

As shown in FIG. 9, the arrangement of the axial fans 16 in this embodiment is similar to that in FIG. 8. Yet, a predetermined degree of offset between the axial fans 16 is applied to this embodiment.

As shown in FIG. 10, the axial fans 16 of this embodiment are arranged at the opposing ventilating sides 140 and both of them are exhausting-type fans.

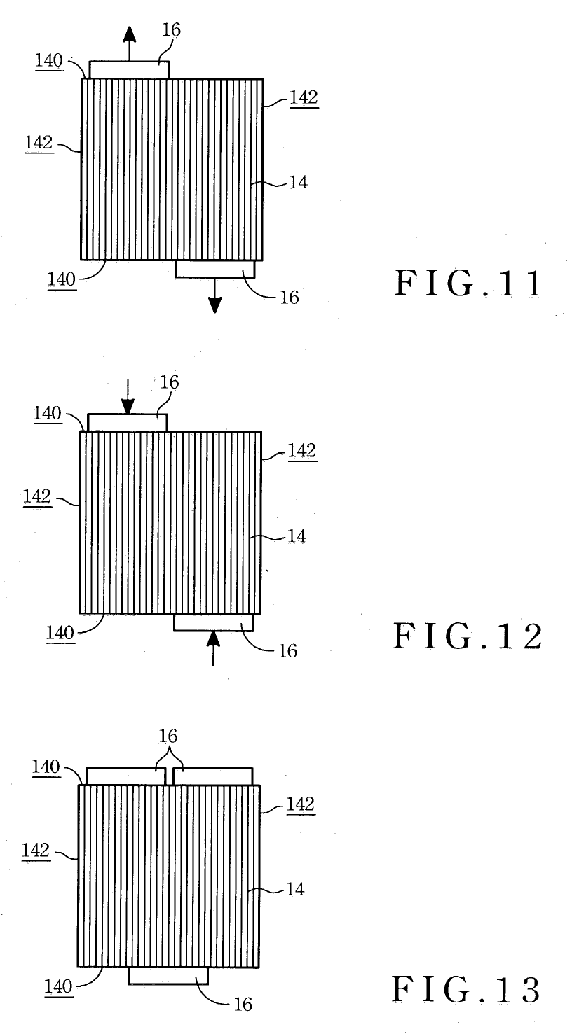

As shown in FIG. 11, the axial fans 16 of this embodiment are arranged at the opposing ventilating sides 140, and both of them are exhausting-type fans though. Yet, an offset arrangement between axial fans 16 similar to that in FIG. 9 is applied.

As shown in FIG. 12, the arrangement of the axial fans 16 in this embodiment is similar to that in FIG. 11. However, both axial fans 16 of this embodiment are sucking-type fans.

In each of the third to the tenth embodiments of the present invention (FIG. 5 to FIG. 12, respectively), the heat-fin 14 has parallel inter-fin slots 141. Nevertheless, for a skilled person in the art, it is quite easy to have the arrangement of the inter-fin slots 141 to be modified to other types of arrangements; in particular, the crossed type of inter-fin slots 141.

Referring now to FIG. 13, a schematic view of an eleventh embodiment of the lateral fan-sink in accordance with the present invention is shown. In this embodiment, one ventilating side 140 of the heat-fin 14 mounts two axial fans 16, while the opposing ventilating side 140 mounts only one axial fan 16.

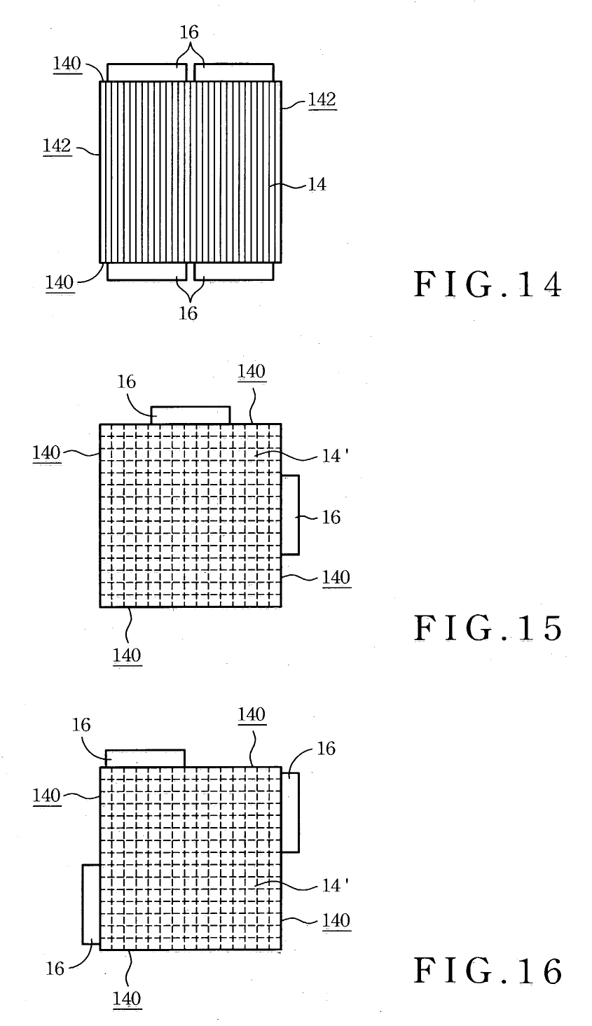

Referring now to FIG. 14, a schematic view of a twelfth embodiment of the lateral fan-sink in accordance with the present invention is shown. In this embodiment, every of the opposing ventilating sides 140 of the heat-fin 14 mounts two axial fans 16.

Referring now to FIG. 15 a schematic view of a thirteenth embodiment of the lateral fan-sink in accordance with the present invention is shown. In this embodiment, the heat-fin 14′ has crossed inter- fin slots, so that the square heat-fin 14′ has all four lateral sides as the ventilating sides 140. Also, this embodiment includes two axial fans 16 mounted at adjacent ventilating sides 140.

Referring now to FIG. 16, a schematic view of a fourteenth embodiment of the lateral fan-sink in accordance with the present invention is shown. In this embodiment, the square heat-fin 14′ with crossed inter-fin slots provides three of its ventilating sides to install three axial fans 16, respectively.

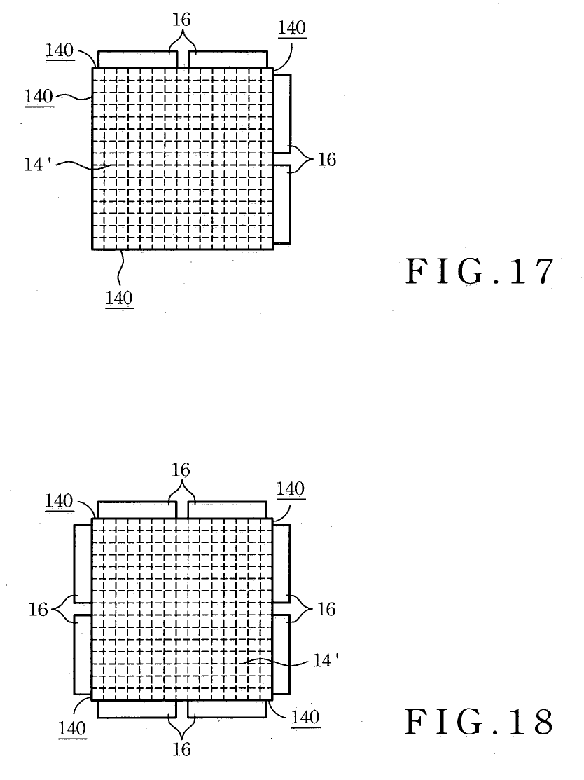

Referring now to FIG. 17, a schematic view of a fifteenth embodiment of the lateral fan-sink in accordance with the present invention is shown. In this embodiment, four axial fans 16 of the fan-sink are mounted equally at two adjacent ventilating sides 140 of the heat-fin 14′.

Referring now to FIG. 18, a schematic view of a sixteenth embodiment of the lateral fan-sink in accordance with the present invention is shown. In this embodiment, each of all four ventilating sides 140 of the square heat-fin 14′ mounts two adjacent axial fans 16.

Though the description of the foregoing eleventh through sixteenth embodiments of the present invention does not point out specifically the type of the axial fan 16, yet, in practice as well as according to the previous disclosure of the first through the tenth embodiments of the present invention, any of the axial fans 16 above can be a sucking-type or a exhausting-type fan. Equally important is that the arrangement of the axial fans 16 in every embodiment shall take the relationship of the fan-sink, the electronic device and the printed circuit board into consideration. However, such consideration is obvious to the skilled in the art after knowing the technique taught in this specification, and so will be omitted herein.

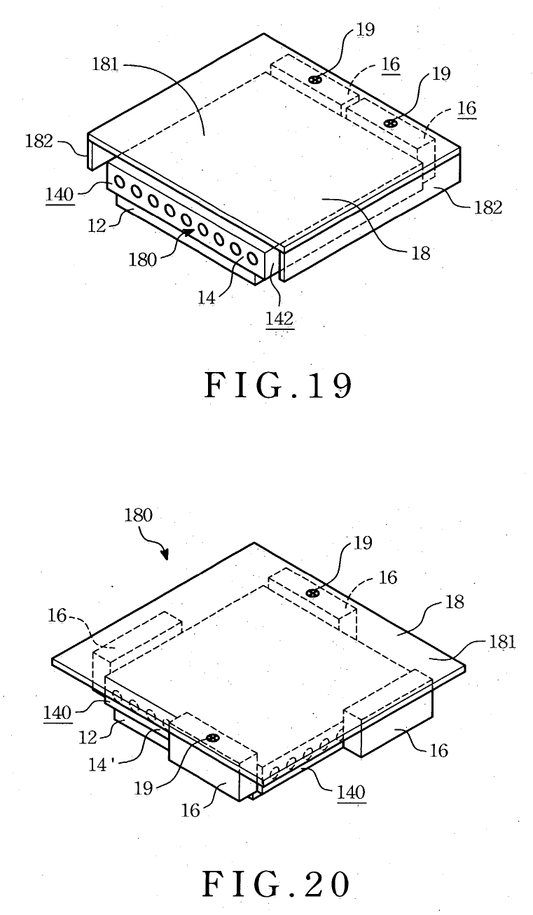

Referring now to FIG. 19, a schematic view of a seventeenth embodiment of the lateral fan-sink in accordance with the present invention is shown. In this embodiment, the arrangement of the heat-fin 14 and the axial fans 16 is the same as that of the first embodiment in FIG. 3B. The major difference between this seventeenth embodiment and the first embodiment, any of foregoing embodiments as well, is that this embodiment includes an air shield 18 mounted over the axial fans 16 and extending to cover the whole area above the inter-fin slots 140 of the heat-fin 14. Upon such an arrangement, the forced flow generated by the axial fans 16 can be restricted to flow only between the heat-fin 14 and the air shield 18. Thereby, the efficiency of the flow for heat exchange can be enhanced to a substantial extend.

As shown in FIG. 19, the air shield 18 can further include 1 top plate 181 shading the heat-fin 14 and two skirt plates 182 extending downward from edges of the top plate 181 at the respective non-flow sides 142.

Referring now to FIG. 20, a schematic view of an eighteenth embodiment of the lateral fan-sink in accordance with the present invention is shown. In this embodiment, the fan-sink includes a heat-fin 14′ with crossed inter-fin slots 141, four axial fans 16 having an arrangement same as that in FIG. 4B, and an air shield 18 formed as a top plate 181 mounted commonly over the axial fans 16 only.

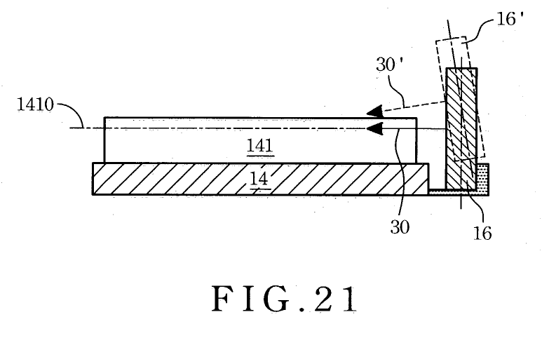

In the present invention, the forced flow introduced by the axial fan 16 can be adjusted to be a flow parallel to the inter-fin slots 141, or at a predetermined angle with the inter-fin slots 141. Referring now to FIG. 21, a cross-sectional view showing the relationship between the axial fan 16 and the heat-fin 14 of the lateral airflow fan-sink for electronic devices in accordance with the present invention is shown. As illustrated, an arrangement of the axial fan 16 is symbolized by solid lines while another arrangement is symbolized by dashed lines. In the embodiment of solid lines, the direction 30 of forced flow generated by the axial fan 16 is parallel to the slot-stretching lines 1410 of the inter-fin slots 141. On the other hand, in the embodiment of dashed lines, the direction 30′ of forced flow generated by the dashed-lined axial fan 16′ forms a predetermined angle with the slot-stretching lines 1410 of the inter-fin slots 141. Yet, it is obvious that the predetermined angle can only be small so that the axial fan 16′ won't slant too close to occupy the open heat-dissipation space over the heat-fin 14.

Apparently, by providing the lateral airflow fan-sink for electronic devices of the present invention which includes several axial fans around a heat-fin so as to produce straight forced flows to flow or wipe along inter-fin slots of the heat-fin and also to free the heat-dissipation space right above the heat-fin, the overall heat-dissipation efficiency of the fan-sink can thus be improved and the operational jeopardy from breakdown of all axial fans can be totally avoided.

While the present invention has been particularly shown and described with reference to a preferred embodiment, it will be understood by those skilled in the art that various changes in form and detail may be without departing from the spirit and scope of the present invention.

I claim:

1. A lateral airflow fan-sink for electronic devices, comprising:
a heat-fin with a plurality of inter-fin slots, defining opposing sides thereof connected longitudinally by the inter-fin slots as opposing ventilating sides; and
a plurality of axial fans, mounted at the ventilating sides for generating respective forced flow flowing along the inter-fin slots.

2. The lateral airflow fan-sink for electronic devices according to claim 1, wherein said axial fans include at least a sucking-type fan.

3. The lateral airflow fan-sink for electronic devices according to claim 1, wherein said axial fans include at least an exhausting-type fan.

4. The lateral airflow fan-sink for electronic devices according to claim 1 further includes an air shield mounted over said axial fans so as to have said forced flow only flow between said heat-fin and the air shield.

5. The lateral airflow fan-sink for electronic devices according to claim 1, wherein each of said ventilating sides mounts at least one said axial fan.

6. The lateral airflow fan-sink for electronic devices according to claim 5, wherein said two fans mounted respectively at said opposing ventilating sides include a sucking-type fan and an exhausting-type fan.

7. The lateral airflow fan-sink for electronic devices according to claim 5, wherein said two fans mounted respectively at said opposing ventilating sides are two sucking-type fans.

8. The lateral airflow fan-sink for electronic devices according to claim 5, wherein said two fans mounted respectively at said opposing ventilating sides are two exhausting-type fans.

9. The lateral airflow fan-sink for electronic devices according to claim 1, wherein two said opposing ventilating sides include only one said axial fan.

10. A lateral airflow fan-sink for electronic devices, comprising:
a heat-fin with a plurality of parallel inter-fin slots, defining two opposing sides thereof connected longitudinally by the inter-fin slots as opposing ventilating sides; and
four axial fans for generating respective forced flow flowing along the inter-fin slots, each of the ventilating sides mounting two of the axial fans.

11. The lateral airflow fan-sink for electronic devices according to claim 10, wherein said axial fans include at least a sucking-type fan.

12. The lateral airflow fan-sink for electronic devices according to claim 10, wherein said axial fans include at least an exhausting-type fan.

13. The lateral airflow fan-sink for electronic devices according to claim 10 further includes an air shield mounted over said axial fans so as to have said forced flow only flow between said heat-fin and the air shield.

14. A lateral airflow fan-sink for electronic devices, comprising:
a heat-fin with a plurality of crossed inter-fin slots, defining any two opposing sides thereof connected longitudinally by the inter-fin slots as opposing ventilating sides; and
four axial fans, mounted at the ventilating sides for generating respective forced flow flowing along the inter-fin slots.

15. The lateral airflow fan-sink for electronic devices according to claim 14, wherein said axial fans include at least a sucking-type fan.

16. The lateral airflow fan-sink for electronic devices according to claim 14, wherein said axial fans include at least an exhausting-type fan.

17. The lateral airflow fan-sink for electronic devices according to claim 14 further includes an air shield mounted over said axial fans so as to have said forced flow only flow between said heat-fin and the air shield.

18. A lateral airflow fan-sink for electronic devices, comprising a heat-fin having a plurality of inter-fin slots, defining any two opposing sides thereof connected longitudinally by the inter-fin slots as opposing ventilating sides, each of the ventilating sides mounting a plurality of axial fans for generating respective forced flow flowing along the inter-fin slots.

19. The lateral airflow fan-sink for electronic devices according to claim 18 further includes an air shield mounted over said axial fans so as to have said forced flow only flow between said heat-fin and the air shield.
